(19) United States
(12) Patent Application Publication
(10) Pub. No.: US 2012/0194214 A1
(43) Pub. Date: Aug. 2, 2012

(54) EQUIPMENT AND METHOD TO CLASSIFY SEMICONDUCTOR PACKAGES

(75) Inventors: Yo-se EUM, Cheonan-si (KR); Dong-Chul Han, Cheonan-si (KR); Yong-Ki Kim, Asan-si (KR); Sang-Geun Kim, Cheonan-si (KR); Ju-Li Kang, Cheonan-si (KR)

(73) Assignee: Samsung Electronics Co., Ltd., Suwon-si (KR)

(21) Appl. No.: 13/362,458

(22) Filed: Jan. 31, 2012

(30) Foreign Application Priority Data
Feb. 1, 2011 (KR) 10-2011-0010345

(51) Int. Cl. G01R 31/26

(52) U.S. Cl. 324/759.03

(57) ABSTRACT

An equipment and method to classify semiconductor packages diced on a substrate into defective and non-defective semiconductor packages includes a loading preparation table to receive a plurality of semiconductor packages to be inspected, a first inspection unit to inspect and classify the semiconductor packages received at the loading preparation table into normal semiconductor packages and defective semiconductor packages, a temporary loading table to temporarily receive at least a portion of the normal semiconductor packages, a first loading picker to transfer the defective semiconductor packages from the loading preparation table to a defective package loading tray and to transfer the normal semiconductor packages from the temporary loading table to the loading preparation table, and a second loading picker to transfer the normal semiconductor packages from the loading preparation table to a normal package loading tray.

### CROSS-REFERENCE TO RELATED APPLICATIONS

This application claims priority from and the benefit under 35 USC §119 of Korean Patent Application No. 10-2011-0010345, filed on Feb. 1, 2011, in the Korean Intellectual Property Office (KIPO), the disclosure of which is incorporated herein by reference.

### BACKGROUND

1. Field

Exemplary embodiments of the present general inventive concept relate to an equipment and method to classify semiconductor packages diced on a substrate into defective and non-defective semiconductor packages.

2. Description of the Background

A visual inspection is performed to sort semiconductor packages into defective and non-defective semiconductor packages. A transfer picker and a loading picker are used to load the classified semiconductor packages in a loading tray.

### SUMMARY

Exemplary embodiments of the present general inventive concept provide equipment to classify semiconductor packages, which can simplify sorting processes while reducing the sorting process time.

Exemplary embodiments of the present general inventive concept provide a method to classify semiconductor packages, which can simplify sorting processes while reducing the sorting process time.

These and other features and utilities of the present general inventive concept will be described in or be apparent from the following description of exemplary embodiments.

Exemplary embodiments of the present general inventive concept provide an equipment to classify semiconductor packages, the equipment including a loading preparation table to receive a plurality of semiconductor packages to be inspected; a first inspection unit to inspect and classify the semiconductor packages received at the loading preparation table into normal semiconductor packages and defective semiconductor packages; a temporary loading table to temporarily receive at least a portion of the normal semiconductor packages; a first loading picker to transfer the defective semiconductor packages from the loading preparation table to a defective package loading tray and to transfer the normal semiconductor packages from the temporary loading table to the loading preparation table; and a second loading picker to transfer the normal semiconductor packages from the loading preparation table to a normal package loading tray.

Exemplary embodiments of the present general inventive concept provide a method of classifying semiconductor packages, the method including receiving a plurality of semiconductor packages to be inspected in a loading preparation table; inspecting the semiconductor packages and classifying the semiconductor packages into normal semiconductor packages and defective semiconductor packages; transferring a plurality of normal semiconductor packages from the loading preparation table to a temporary loading table; transferring, by a first loading picker, the defective semiconductor packages from the loading preparation table to a defective package loading tray and transferring the normal semiconductor packages from the temporary loading table to the loading preparation table; and transferring, by a second loading picker, the normal semiconductor packages from the loading preparation table to a normal package loading tray.

Exemplary embodiments of the present general inventive concept provide an equipment to classify semiconductor packages, the equipment including a loading preparation table to receive a plurality of semiconductor packages to be inspected; a first inspection unit to inspect and classify the semiconductor packages received at the loading preparation table into normal semiconductor packages and defective semiconductor packages; a temporary loading table to temporarily receive at least a portion of the normal semiconductor packages; a first loading picker to transfer the defective semiconductor packages from the loading preparation table to a defective package loading tray; and a second loading picker to only transfer the normal semiconductor packages from the loading preparation table to a normal package loading tray.

Exemplary embodiments of the present general inventive concept provide a method of classifying semiconductor packages, the method including receiving a plurality of semiconductor packages to be inspected in a loading preparation table; inspecting the semiconductor packages and classifying the semiconductor packages into normal semiconductor packages and defective semiconductor packages; transferring, by a first loading picker, the defective semiconductor packages from the loading preparation table to a defective package loading tray; and transferring, by a second loading picker, the normal semiconductor packages from the loading preparation table to a normal package loading tray, the second loading picker only transferring the normal semiconductor packages from the loading preparation table to a normal package loading tray

Additional features and utilities of the present general inventive concept will be set forth in part in the description which follows and, in part, will be obvious from the description, or may be learned by practice of the general inventive concept.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a simplified plan view of equipment to classify semiconductor packages according to exemplary embodiments of the present general inventive concept;

FIG. 2 is a flowchart illustrating a method of sorting semiconductor packages according to exemplary embodiments of the present general inventive concept;

FIG. 3 illustrates a single substrate cut into a plurality of semiconductor packages according to exemplary embodiments of the present general inventive concept; and

FIG. 4 is a table showing the results of a simulation experiment for measuring the time required to load the semiconductor packages according to exemplary embodiments of the present general inventive concept.

### DETAILED DESCRIPTION OF THE ILLUSTRATED EMBODIMENTS

Reference will now be made in detail to exemplary embodiments of the present general inventive concept, examples of which are illustrated in the accompanying drawings, wherein like reference numerals refer to the like elements throughout. Exemplary embodiments are described below in order to explain the present general inventive concept while referring to the figures.

The use of the terms “a” and “an” and “the” and similar referents in the context of this description (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

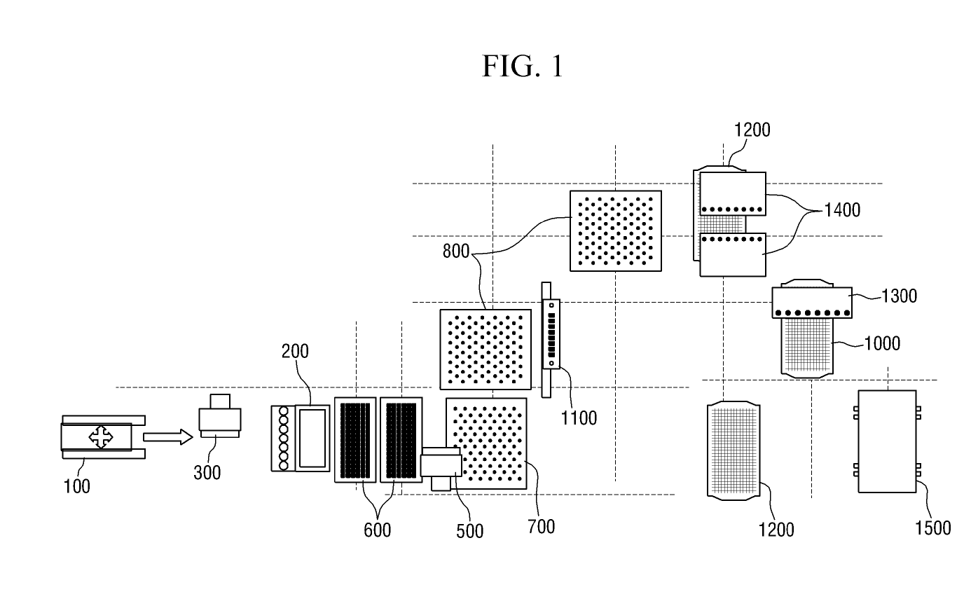

Hereinafter, equipment to classify semiconductor packages according to exemplary embodiments of the present general inventive concept will be described in detail with reference to FIGS. 1 to 4. FIG. 1 is a simplified plan view of equipment to classify semiconductor packages according to an exemplary embodiment of the present general inventive concept.

FIG. 1 is a simplified plan view of equipment to classify semiconductor packages according to exemplary embodiments of the present general inventive concept. Referring to FIG. 1, the equipment to classify semiconductor packages according to exemplary embodiments includes a dicing section 100, a cleaning section 200, a unit picker 300, a buffer picker 500, a buffer table 600, first and second inspection units (not shown), a reverse table 700, a loading preparation table 800, a temporary loading table 1100, a first loading picker 1300, a second loading picker 1400, and a tray picker 1500.

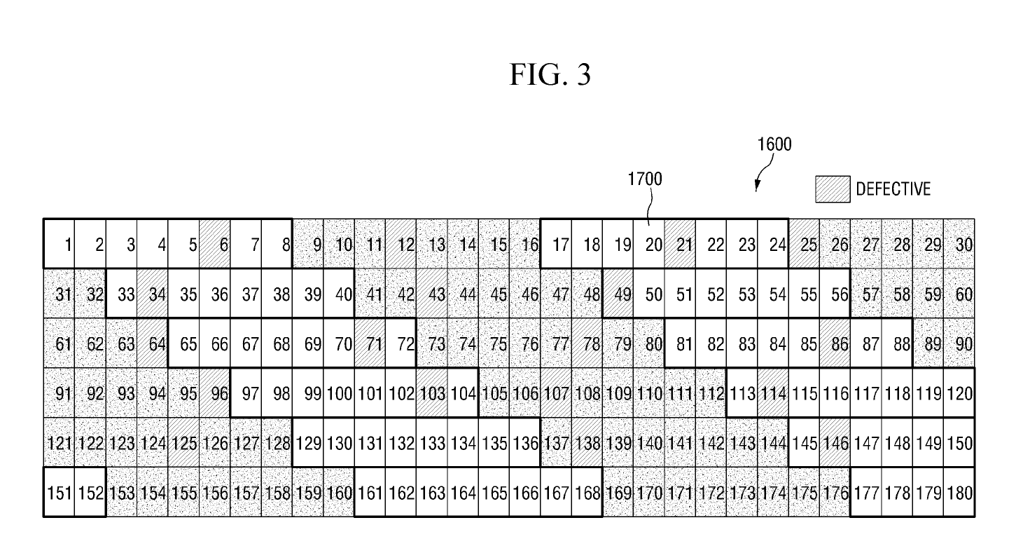

The dicing section 100 cuts a substrate 1600, as shown in FIG. 3, into a plurality of semiconductor package units, each unit containing a single chip. During semiconductor packaging, a plurality of chips may be attached to the substrate 1600 through solder balls. The dicing section 100 may include a blade to cut the substrate 1600 into semiconductor packages 1700, as shown in FIG. 3.

In order to form the semiconductor packages 1700 for inspection, a dicing operation may be performed in X- and Y-directions; however, the dicing operation is not limited thereto such that the dicing operation need not be, for example, in perpendicular directions. The cleaning section 200 cleans and dries the semiconductor package 1700 to prepare the semiconductor package 1700 to be inspected. The unit picker 300 transfers the semiconductor package 1700 to a cleaning location at which the cleaning section 200 removes contaminants generated during the dicing operation.

The unit picker 300 transports the semiconductor packages 1700 formed by the dicing operation to the cleaning location as described above and then transports the cleaned semiconductor package 1700 to a buffer table 600.

The attachment of the solder balls of the semiconductor package 1700 is inspected at the buffer table 600. The semiconductor package 1700 may be transferred to the buffer table 600 with the solder balls facing upward. The first inspection unit, such as a visual inspection unit, may inspect whether the solder balls are properly attached. The first inspection unit may be a visual device or any other device that can check the attachment of solder balls.

The inspection is performed to classify the semiconductor packages 1700 into normal semiconductor packages having good solder ball attachments and defective semiconductor packages having poor solder ball attachments. Information about the result of the inspection may be stored in a controller (not shown) of the classifying equipment and used later to distinguish normal semiconductor packages from defective semiconductor packages.

The buffer picker 500 transports the semiconductor package 1700 after the inspection of the solder ball attachments from the buffer table 600 to the reverse table 700. The reverse table 700 includes a reversing unit (not shown) that turns the semiconductor package 1700 upside down so that the solder balls face down. The upside-down semiconductor package 1700 may be transported to the loading preparation table 800.

A mark indicated on the semiconductor package 1700 is inspected at the loading preparation table 800, and the semiconductor package 1700 is in a standby state before being received in a tray, e.g., one of a defective package loading tray 1000 and a normal package loading tray 1200. At the loading preparation table 800, the second inspection unit, which may be a visual inspection unit, inspects the state of a mark, such as a manufacturer's logo, indicated on the semiconductor package 1700. The mark may become defective during the previous processes, e.g., sorting, cleaning, and the like, applied to the semiconductor packages 1700 such that the defective mark may no longer indicate the details of the semiconductor package 1700. Thus, the mark of the semiconductor package 1700 may be inspected at the loading preparation table 800. The result of the inspection may be stored in the controller of the classifying equipment and be used later to discriminate normal semiconductor packages from defective semiconductor packages.

As described above, the first and second inspection units and respectively inspect whether the solder balls are properly attached and whether the mark is properly indicated on the semiconductor package 1700. The first and second inspection units may be visual devices using a camera or sensors using a laser but are not limited thereto.

The semiconductor packages 1700 are classified into the second normal semiconductor packages and defective semiconductor packages based on the results of the inspections performed by the first and second inspection units. The first and second inspection units may be referred to as primary and secondary inspections.

The first loading picker 1300 may load the defective semiconductor packages from the loading preparation table 800 to the defective package loading tray 1000. The first loading picker 1300 may also transfer some of the second normal semiconductor packages received in the loading preparation table 800 to the temporary loading table 1100. The second normal semiconductor packages transferred to the temporary loading table 100 become or will be referred to as first normal semiconductor packages. The temporary loading table 1100 may be used to hold first normal semiconductor packages before being received in a tray, e.g., the normal package loading tray 1200. Other than location, the first and second normal semiconductor packages may be the same.

Upon transfer of the defective semiconductor packages to the defective package loading tray 1000, the loading preparation table 800 has the same number of vacancies available to the semiconductor packages 1700 as the number of transferred defective semiconductor packages. To fill the vacancies of the loading preparation table 800, the first loading picker 1300 may transfer at least some of the first normal semiconductor packages 1700 loaded in the temporary loading table 1100 to the loading preparation table 800.

In other words, the first loading picker 1300 transfers the semiconductor packages 1700 that are found defective based on the primary and secondary inspections from the loading preparation table 800 to the defective package loading tray 1000 for loading. At the same time or afterwards, the first loading picker 1300 transfers the first normal semiconductor packages 1700 received in the temporary loading table 1100 to the loading preparation table 800 in order to fill the vacancies left by the semiconductor packages 1700 loaded in the defective package loading tray 1000. The first loading picker 1300 may transfer all or some of the first normal semiconductor packages 1700 received in the temporary loading table 1100 to the loading preparation table 800 to fill all or some of the vacancies on the loading preparation table 800 caused by the removal of the defective semiconductor packages transferred to the defective package loading tray 1000. Also, the first normal semiconductor packages 1700 that are more than a number of semiconductor packages loaded in the defective package loading tray 1000 may be transferred to the loading preparation table 800. The first loading picker 1300 may also load the first normal semiconductor packages remaining on the temporary loading table 1100 in the normal package loading tray 1200.

The second loading picker 1400 loads or transfers first and second normal semiconductor packages seated on the loading preparation table 800 on or to the normal package loading tray 1200. By using a picker dedicated for loading the normal semiconductor packages, the sorting process time may be reduced.

The tray picker 1500 supplies the normal package loading tray 1200 and the defective package loading tray 1000 to loading locations.

The unit picker 300, the buffer picker 500, the first loading picker 1300, and the second loading picker 1400 may pick up and load more than 8 semiconductor packages at a time, and may include rubber pads, and may include any materials or shapes that can pick up the semiconductor packages 1700.

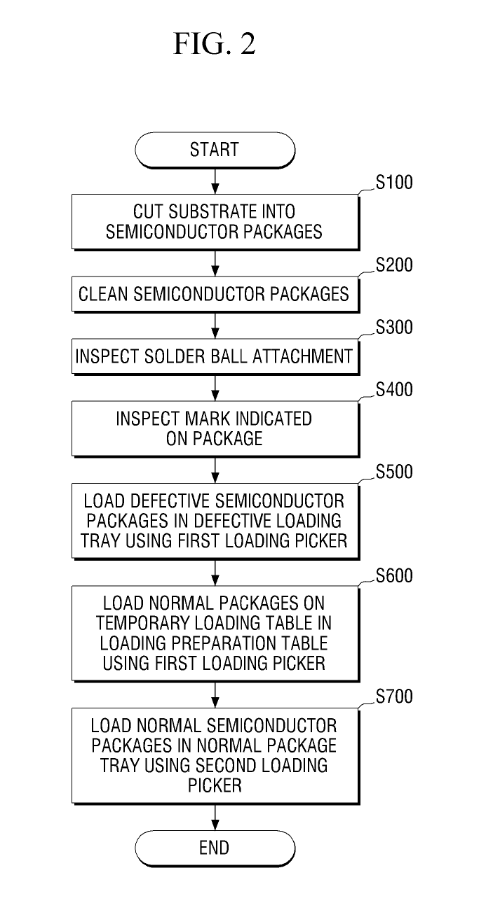

FIG. 2 is a flowchart illustrating a method of sorting semiconductor packages according to exemplary embodiments of the present general inventive concept. Referring to FIGS. 1 and 2, the substrate 1600 is cut into a plurality of semiconductor packages 1700 by the dicing section 100 (S100). A semiconductor packaging process is performed to have a plurality of semiconductor chips arranged on the substrate 1600. The substrate 1600 may be cut by dicing into the plurality of semiconductor packages 1700 to be inspected, each cut semiconductor package 1700 encapsulating a single semiconductor chip.

Each of the plurality of semiconductor packages 1700 is cleaned (S200). In detail, during the dicing operation, the semiconductor package 1700 may be stained by contaminants, which may degrade the electrical performance of a semiconductor chip embedded therein. Thus, the plurality of semiconductor packages 1700 are transferred to the cleaning section 200 by the unit picker 300, and then the plurality of semiconductor packages 1700 are cleaned and dried by or in the cleaning section 200.

After the cleaning operation, an inspection is performed to determine whether solder balls are properly attached on the semiconductor package 1700 (S300). This inspection may be referred to as a primary inspection. More specifically, the cleaned semiconductor package 1700 is transferred to the buffer table 600 by the unit picker 300. The semiconductor package 1700 is seated on the buffer table 600 with the solder balls facing upward. The first inspection unit may be a visual inspection unit and inspects whether the solder balls are properly attached on the semiconductor package 1700. The result of the primary inspection is stored in the controller of the classifying equipment and used later to classify the semiconductor packages 1700 into normal and defective semiconductor packages.

Subsequently, the semiconductor package 1700 is transferred to the loading preparation table 800 and the state of a mark indicated on the semiconductor package 1700 is inspected (S4000). This inspection may be referred to as a secondary inspection. More specifically, after the primary inspection, the semiconductor package 1700 is transferred to the reverse table 700 by the buffer picker 500. Then, the reversing unit of the reverse table 700 flips the semiconductor package 1700 upside down so that the solder balls are disposed face down.

The upside-down semiconductor package 1700 is transferred to the loading preparation table 800 at which the second inspection unit (not shown) inspects whether the mark is indicated properly on the semiconductor package 1700. The second inspection unit may be a visual inspection unit. The mark, such as a manufacturer's logo, may be damaged during previous processes, e.g., sorting, cleaning, and the like. Thus, by inspecting the mark for the damage, it can be determined whether the semiconductor package 1700 is defective.

The result of a secondary inspection performed by the second inspection unit may be stored in the controller of the classifying equipment and used later to determine whether the semiconductor package 1700 is defective.

The first loading picker 1300 loads the semiconductor packages 1700 that are found defective based on the results of the primary and secondary inspections in the defective package loading tray 1000 (S500). In detail, the semiconductor packages 1700 seated on the loading preparation table 800 are sorted into second normal semiconductor packages and defective semiconductor packages based on the results of the primary and secondary inspections stored in the controller of the classifying equipment. The semiconductor packages 1700 classified as defective are loaded in the defective package loading tray 1000 by the first loading picker 1300. The semiconductor packages 1700 may be determined to be defective as a result of either one of the primary and secondary inspections or as a result of both the primary and secondary inspections.

The first loading picker 1300 loads normal semiconductor packages seated on the temporary loading table 1100 on the loading preparation table 800 (S600). More specifically, the first loading picker 1300 transfers the first normal semiconductor packages previously loaded in the temporary loading table 1100 to the loading preparation table 800 to fill vacancies corresponding to a number of defective semiconductor packages transported to the defective package loading tray 1000. Depending on the application, the first normal semiconductor packages 1700 that are more than a number of semiconductor packages transferred to the defective package loading tray 1000 may be transported to the loading preparation table 800.

The first and second normal semiconductor packages loaded in the loading preparation table 800 are loaded in the normal package loading tray 1200 by the second loading picker 1400 (S700). Second normal semiconductor packages classified as normal based on the results of primary and secondary inspections and the first normal semiconductor packages transferred from the temporary loading table 1100 are loaded on the normal package loading tray 1200 by the second loading picker 1400. That is, the second loading picker 1400 loads the first and second normal semiconductor packages in the normal package loading tray 1200. The second loading picker 1400 may load only the first and second normal semiconductor packages in the normal package loading tray 1200. The semiconductor packages 1700 may be determined to be normal as a result of either one of the primary and secondary inspections or as a result of both the primary and secondary inspections. Also, the semiconductor packages 1700 may be determined to be defective as a result of either one of the primary and secondary inspections or as a result of both the primary and secondary inspections.

The first loading picker 1300 loads normal semiconductor packages remaining on the temporary loading table 1100 on the normal package loading tray 1200. That is, the first loading picker 1300 loads the first normal semiconductor packages remaining on the temporary loading table 1100 after replacing the defective semiconductor packages seated on the loading preparation table 800 on the normal package loading tray 1200.

FIG. 3 illustrates a single substrate cut into a plurality of semiconductor packages according to exemplary embodiments of the present general inventive concept. FIG. 3 illustrates a single substrate 1600 that is cut into a plurality of semiconductor packages 1700.

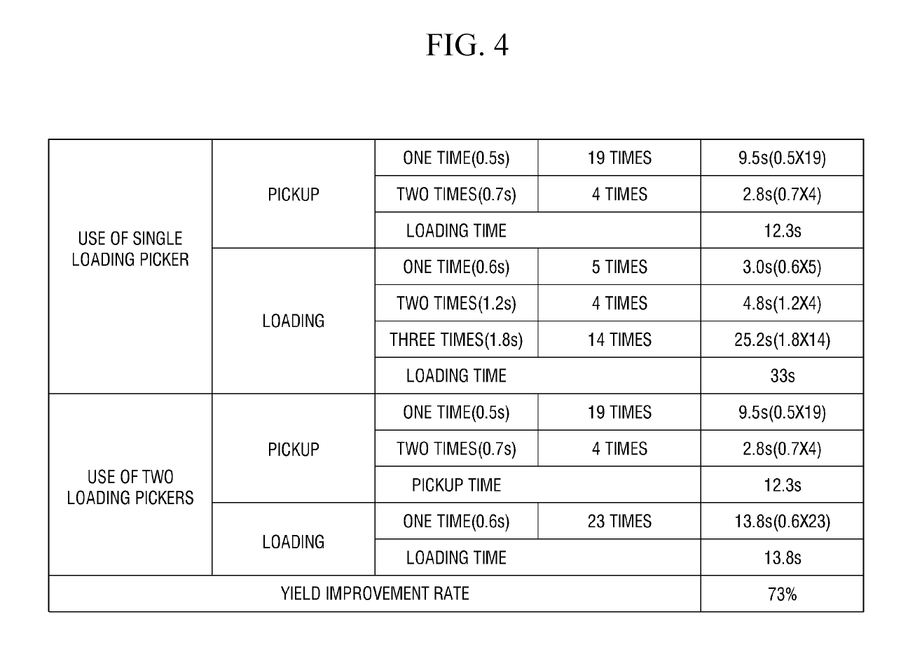

FIG. 4 is a table showing the results of a simulation experiment for measuring the time required to load the semiconductor packages according to exemplary embodiments of the present general inventive concept.

Referring to FIGS. 1, 3 and 4, the substrate 1600 is diced into 180 semiconductor packages 1700. In the simulation experiment, assuming that the percentage of defective semiconductor packages is 10 percent (%), 18 of all 180 of the semiconductor packages 1700 are defective. The defective semiconductor packages are indicated by oblique lines in FIG. 3. That is, the semiconductor packages 1700 numbered 6, 12, 21, 25, . . . , 125, 138, and 146 are defective.

Furthermore, it is assumed herein that a loading picker picks up, transfers, and loads up to 8 semiconductor packages 1700. Considering load capacity, which may be a specification of the loading picker, the semiconductor packages 1700 are partitioned into a plurality of groups, each of which contains 8 semiconductor packages 1700 excluding the last group, which includes the remaining 4 semiconductor packages. In detail, the semiconductor packages 1700 includes groups of 8 semiconductor packages 1700 indicated by dotted shading in the respective rectangles and groups of 8 semiconductor packages 1700 indicated by undotted rectangles. A group of 8 undotted rectangular semiconductor packages 1700 are alternately arranged with a group of 8 dotted rectangular semiconductor packages 1700.

Referring to FIG. 4, when all 8 semiconductor packages 1700 in each group are located in the same row, a one-time pickup may be performed to transfer all of them at a time without moving or operating a picker. When 8 semiconductor packages 1700 in each group are located in two separate rows, a two-time pickup may be performed to transfer the 8 semiconductor packages 1700 by moving or operating a picker. For example, a group containing semiconductor packages 1700 numbered 1 through 8 may be picked up simultaneously or at a same time while a group containing semiconductor packages 1700 numbered 25 through 32 may be picked up twice or in two pickups.

When each of the semiconductor packages 1700 of a group picked up by a picker are normal semiconductor packages, a one-time loading may be performed to load all of the semiconductor packages 1700 in the normal package loading tray 1200 simultaneously or at a same time. For example, the one-time loading may be performed on each of five groups containing semiconductor packages 1700 numbered 129 through 136, semiconductor packages 1700 numbered 153 through 160, semiconductor packages 1700 numbered 161 through 168, semiconductor packages 1700 numbered 169 through 176, and semiconductor packages 1700 numbered 177 through 180.

When a first or last one of 8 semiconductor packages 1700 in a group is defective, a two-time loading is performed. For example, when a first one of the 8 semiconductor packages is defective, the first defective semiconductor package is loaded in the defective package loading tray 1000 while the remaining 7 semiconductor packages are loaded in the normal package loading tray 1200. For example, the two-time loading may be performed for each of four groups containing semiconductor packages 1700 numbered 25 through 32, semiconductor packages 1700 numbered 49 through 56, semiconductor packages 1700 numbered 57 through 64, and semiconductor packages 1700 numbered 89 through 96.

When one of the remaining semiconductor packages 1700 excluding the first and last ones in a group is defective, a three-time loading is performed. For example, when a second one of the 8 semiconductor packages is defective, the first semiconductor package is loaded in the normal package loading tray 1200, the second one is loaded in the defective package loading tray 1000, and the remaining six are loaded in the normal package loading tray 1200. For example, the three-time loading may be performed for each of 14 groups containing semiconductor packages 1700 numbered 1 through 8, semiconductor packages 1700 numbered 9 through 16, semiconductor packages 1700 numbered 17 through 24, semiconductor packages 1700 numbered 33 through 40, semiconductor packages 1700 numbered 41 through 49, semiconductor packages 1700 numbered 65 through 72, semiconductor packages 1700 numbered 73 through 80, semiconductor packages 1700 numbered 81 through 88, semiconductor packages 1700 numbered 97 through 104, semiconductor packages 1700 numbered 105 through 112, semiconductor packages 1700 numbered 113 through 120, semiconductor packages 1700 numbered 121 through 128, semiconductor packages 1700 numbered 137 through 144, and semiconductor packages 1700 numbered 145 through 152.

The results of simulation experiments performed when one and two loading pickers are used according to the above assumptions will now be described in detail with reference to FIG. 4.

As shown in the Table of FIG. 4, when a single loading picker is used, one-time pickups and two-time pickups are performed 19 times and 4 times, respectively in which the total pickup time is 12.3 seconds. When two loading pickers are used, the same total pickup time is required.

More specifically, since a single loading picker has to load normal and defective semiconductor packages, the loading picker reciprocates between the normal and defective package loading trays 1200 and 1000, respectively. Thus, loading has to be performed up to three times in order to load all of the 8 semiconductor packages 1700. Consequently, one-time loading, two-time loading, and three-time loading are performed five times, four times, and fourteen times, respectively, to load 180 semiconductor packages 1700 in the normal and defective package loading trays 1200 and 1000, respectively, and the total loading time is 33 seconds.

When two loading pickers are used, one of the two loading pickers may be dedicated to loading the normal semiconductor packages 1700 in the normal package loading tray 1200. The first loading picker 1300 may be used to replace defective semiconductor packages on the semiconductor preparation table 800 with normal ones while the second loading picker 1400 may be used only for loading existing normal semiconductor packages and the normal semiconductor packages substituted for the defective ones from the loading preparation table 800 in the normal package loading tray 1200.

Thus, since time required to load 180 semiconductor packages 1700 in the normal package loading tray 1200 is equal to time required for the second loading picker 1400 to load them, one-time loading is performed 23 times and the total loading time is 13.8 seconds.

That is, when two loading pickers are used, the same pickup time is required as when a single picker is used. However, the total loading time is 33 seconds when a single loading picker is used while a total of 13.8 seconds are required when two loading pickers are used and one of the loading pickers is dedicated to transferring normal semiconductor packages 1700 from the loading preparation table 800 to the normal package loading tray 1200.

A yield improvement rate (1.73) is calculated by dividing total pickup time and total loading time (12.3+13.8) measured when two loading pickers are used by total pickup time and total loading time (12.3+33) measured when a single picker is used. Thus, when two loading pickers are used, a yield is improved by 73% compared to when a single loading picker is used.

Although a few exemplary embodiments of the present general inventive concept have been shown and described, it will be appreciated by those skilled in the art that changes may be made in these exemplary embodiments without departing from the principles and spirit of the general inventive concept, the scope of which is defined in the appended claims and their equivalents.

1. An equipment to classify semiconductor packages, the equipment comprising:
a loading preparation table to receive a plurality of semiconductor packages to be inspected;
a first inspection unit to inspect and classify the semiconductor packages received at the loading preparation table into normal semiconductor packages and defective semiconductor packages;
a temporary loading table to temporarily receive at least a portion of the normal semiconductor packages;
a first loading picker to transfer the defective semiconductor packages from the loading preparation table to a defective package loading tray and to transfer the normal semiconductor packages from the temporary loading table to the loading preparation table; and
a second loading picker to transfer the normal semiconductor packages from the loading preparation table to a normal package loading tray.

2. The equipment of claim 1, further comprising a dicing section to cut a substrate into the plurality of semiconductor packages to be inspected.

3. The equipment of claim 2, further comprising a cleaning section to clean and dry the plurality of semiconductor packages to be inspected.

4. The equipment of claim 1, further comprising a second inspection unit to determine whether solder balls are properly attached on the plurality of semiconductor packages to be inspected and to classify the semiconductor packages into the normal semiconductor packages and the defective semiconductor packages.

5. The equipment of claim 4, further comprising a reversing unit to turn the plurality of semiconductor packages inspected by the second inspection unit upside down.

6. The equipment of claim 4, wherein the first loading picker transfers the defective semiconductor packages from the loading preparation table to the defective package loading tray according to a result of at least the inspection by the first inspection unit or the inspection by the second inspection unit.

7. The equipment of claim 1, wherein the first loading picker loads the normal semiconductor packages from the temporary loading table to the normal package loading tray.

8. The equipment of claim 3, further comprising a unit picker to transfer the plurality of semiconductor packages subjected to the cleaning from the cleaning section.

9. The equipment of claim 4, further comprising a buffer picker to transfer the plurality of semiconductor packages inspected by the second inspection unit.

10. The equipment of claim 1, further comprising a tray picker to transport the defective package loading tray and the normal package loading tray.

11. The equipment of claim 4, wherein at least one of the first inspection unit and second inspection unit includes a visual device or a sensor comprising a laser.

12. The equipment of claim 1, wherein the first inspection unit inspects marks indicated on the plurality of semiconductor packages to be inspected.

13. The equipment of claim 1, wherein the second loading picker only transfers the normal semiconductor packages from the loading preparation table to the normal package loading tray.

14. The equipment of claim 1, wherein the first loading picker transfers the normal semiconductor packages from the loading preparation table to the temporary loading table.

15-28. (canceled)

29. An equipment to classify semiconductor packages, the equipment comprising:
a loading preparation table to receive a plurality of semiconductor packages to be inspected;
a first inspection unit to inspect and classify the semiconductor packages received at the loading preparation table into normal semiconductor packages and defective semiconductor packages;
a temporary loading table to temporarily receive at least a portion of the normal semiconductor packages;
a first loading picker to transfer the defective semiconductor packages from the loading preparation table to a defective package loading tray; and
a second loading picker to only transfer the normal semiconductor packages from the loading preparation table to a normal package loading tray.

30. The equipment of claim 29, wherein the first loading picker transfers the normal semiconductor packages from the temporary loading table to the loading preparation table.

31. The equipment of claim 29, wherein the first loading picker transfers the normal semiconductor packages from loading preparation table to the temporary loading table.

32. The equipment of claim 29, wherein the first loading picker transfers the normal semiconductor packages from the temporary loading table to the normal package loading tray.

33-36. (canceled)
